(19) United States
(12) Patent Application Publication
(10) Pub. No.: US 2015/0213999 A1
(43) Pub. Date: Jul. 30, 2015

(54) Charged Particle Beam Apparatus

(71) Applicant: Hitachi High-Technologies Corporation, Minato-ku, Tokyo (JP)

(72) Inventors: Yusuke Ominami, Tokyo (JP); Noriyuki Sakuma, Tokyo (JP); Shinsuke Kawanishi, Tokyo (JP); Masahiko Ajima, Tokyo (JP); Sukehiro Ito, Tokyo (JP)

(21) Appl. No.: 14/422,454

(22) PCT Filed: Jul. 1, 2013
(86) PCT No.: PCT/JP2013/067967

§ 371 Date: Feb. 19, 2015

(30) Foreign Application Priority Data
Sep. 27, 2012 (JP) 2012-213382

(51) Int. Cl. H01J 37/16; H01J 37/26

(52) U.S. Cl. CPC H01J 37/16; H01J 37/26; H01J 2237/164

(57) ABSTRACT

The ordinary charged particle beam apparatus works on the assumption that signals are detected while its diaphragm and the sample are being positioned close to each other. This structure is not suitable for observing a sample with a prominently uneven surface in a gas atmosphere at atmospheric pressure or at a pressure substantially equal thereto. The present invention provides a charged particle beam apparatus that separates its charged particle optical tube from the space in which the sample is placed. The apparatus includes a detachable diaphragm that lets a primary charged particle beam permeate or pass therethrough. Installed in the space where the sample is placed is a detector that detects secondary particles discharged from the sample irradiated with the primary charged particle beam.

### TECHNICAL FIELD

The present invention relates to a charged particle beam apparatus capable of observing a sample in a gas atmosphere at atmospheric pressure or at a predetermined pressure.

### BACKGROUND ART

Scanning electron microscopes (SEM) or transmission electron microscopes (TEM) are used to observe infinitesimal regions of an object. Generally, these devices evacuate an enclosure that houses a sample to get images of the sample in a vacuum state. However, biochemical samples or liquid samples can be damaged in vacuum or can be changed in nature therein. Meanwhile, there has been a strong need for observing such samples under electron microscope. In recent years, there have been developed SEM equipment and sample holding devices that allow an observation target sample to be observed at atmospheric pressure.

In principle, these devices set up a permeable diaphragm or a tiny through hole that allows an electron beam to pass therethrough between an electron optical system and the sample, thereby separating the vacuum state from the atmospheric state. Common to these devices is the provision of the diaphragm between the sample and the electron optical system.

For example, Patent Document 1 discloses an SEM in which an electron optical tube has its electron source oriented downward and its objective lens oriented upward. The end of the electron optical tube emitting an electron beam has a diaphragm with an O-ring allowing the electron beam to pass through an emitting hole of the tube. According to the invention described in this literature, the observation target sample is directly placed on the diaphragm. The sample is then irradiated from below with a primary electron beam so that reflected or secondary electrons are detected for SEM observation. The sample is held in a space made up of the diaphragm and a circular member surrounding the diaphragm. Furthermore, this space is filled with liquid such as water.

### PRIOR ART LITERATURE

### Patent Document

Patent Document 1: JP-2009-158222-A (U.S. Unexamined Patent Application Publication No. 2009/0166536)

### SUMMARY OF THE INVENTION

### Problems to be Solved by the Invention

The ordinary charged particle beam apparatuses have been manufactured so as to be dedicated to making observations in a gas atmosphere at atmospheric pressure or at a pressure substantially equal thereto. There have existed no devices capable of simply making observations under an ordinary high-vacuum charged particle microscope in a gas atmosphere at atmospheric pressure or at a pressure approximately equal thereto.

For example, the SEM described in Patent Document 1 is a very special device in structural terms. The device is incapable of making SEM observations in the ordinary high-vacuum atmosphere.

Moreover, methods of the existing technology are based on the assumption that signals are detected in a state where the diaphragm and the sample are positioned close to each other. For this reason, the existing device structure is not suitable for observing, say, a sample with a prominently uneven surface.

The present invention has been made in view of the above circumstances and provides a charged particle beam apparatus that permits observation of the sample in an air atmosphere or in a gas atmosphere without significantly changing the structure of the existing high-vacuum charged particle microscope, the charged particle beam apparatus being further capable of observing an uneven sample.

### Means for Solving the Problem

To solve the above-described problem, there may be adopted, for example, the structures described in the appended claims of this application.

This application includes multiple means for solving the above-described problem, one such means including: a charged particle optical tube that irradiates a sample with a primary charged particle beam; a vacuum pump that evacuates the inside of the charged particle optical tube; a diaphragm arranged to separate a space in which the sample is placed from the charged particle optical tube, the diaphragm being detachable and allowing the primary charged particle beam to permeate or pass therethrough; and a detector that detects secondary particles discharged from the sample being irradiated with the primary charged particle beam. The detector is installed in the space where the sample is placed.

### Effects of the Invention

According to the present invention, there is provided a charged particle beam apparatus that permits observation of the sample in an air atmosphere or in a gas atmosphere without significantly changing the structure of the existing high-vacuum charged particle microscope. The charged particle beam apparatus is further capable of observing a sample having an uneven surface.

Further problems, structures, and advantages other than those stated above will become apparent upon a reading of the ensuing explanation of some embodiments of the present invention.

### BRIEF DESCRIPTION OF THE DRAWINGS

FIG. 1 is an overall block diagram of a charged particle microscope as a first embodiment of the present invention.

FIG. 2 is a detail plan showing the vicinities of the diaphragm, a sample, and the detector.

FIG. 3 is a set of detail plans of the detector.

FIG. 4 is a set of diagrams explaining the locus of the charged particle beam and the position of the detector.

FIG. 5 shows a typical structure of a charged particle microscope as a second embodiment of the present invention.

FIG. 6 shows another typical structure of the charged particle microscope as the second embodiment.

FIG. 7 shows another typical structure of the charged particle microscope as the second embodiment.

FIG. 8 shows a typical structure of a charged particle microscope as a third embodiment of the present invention.

FIG. 9 is an overall block diagram of a charged particle microscope as a fourth embodiment of the present invention.

### MODE FOR CARRYING OUT THE INVENTION

Some embodiments of the present invention will now be explained with reference to the accompanying drawings.

What follows is an explanation of charged particle beam microscopes as an example of the charged particle beam apparatus. It should be noted that these microscopes are only an example embodying the present invention and that the invention is not limited to the embodiments to be discussed hereunder. The present invention can be applied to scanning electron microscopes, scanning ion microscopes, scanning transmission electron microscopes, a composite device that combines any of these microscopes with sample processing equipment, or analyzer/inspection equipment that applies any of these microscopes.

In this description, the wording “atmospheric pressure” refers to an air atmosphere or a predetermined gas atmosphere and signifies a pressure environment under atmospheric pressure or in a somewhat negatively or positively pressured state. Specifically, the environment is to be at about 10⁵ Pa (atmospheric pressure) to about 10³ Pa.

### First Embodiment

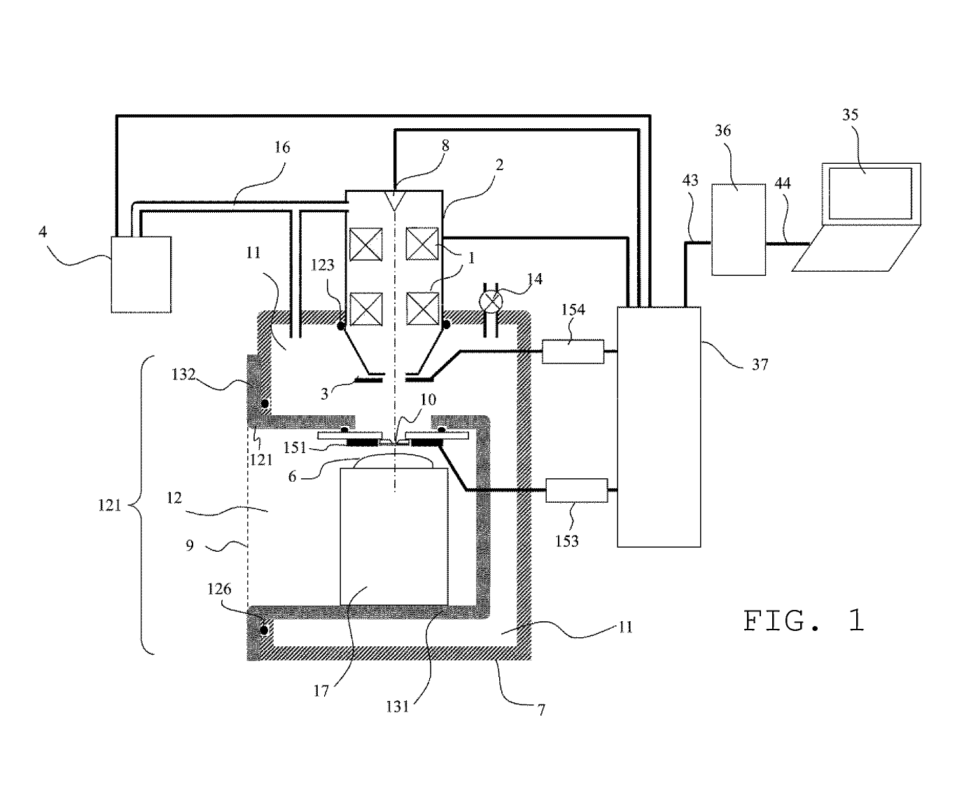

The first embodiment is explained here as the basic mode for carrying out the invention. FIG. 1 is an overall block diagram of a charged particle microscope as the first embodiment. The charged particle microscope shown in FIG. 1 is mainly constituted by a charged particle optical tube 2, a first enclosure 7 (also called the vacuum chamber hereunder where appropriate) that supports the charged particle optical tube against an apparatus installation surface, a second enclosure 121 (also called the attachment hereunder where appropriate) inserted into the first enclosure 7 when used, and a control system that controls these components. When the charged particle microscope is to be used, the inside of the charged particle optical tube 2 and that of the first enclosure are evacuated by a vacuum pump 4. The control system also controls the start and stop of the vacuum pump 4. Although only one vacuum pump 4 is shown, two or more vacuum pumps may be provided alternatively.

The charged particle optical tube 2 is made up of such elements as a charged particle source 8 that generates a charged particle beam, and an optical lens 1 that focuses the generated charged particle beam at the bottom of the tube as a primary charged particle beam for scanning the sample 6. The charged particle optical tube 2 is positioned in a manner protruding into the first enclosure 7 and fixed to the first enclosure 7 by means of a vacuum sealing member 123. The tip of the charged particle optical tube 2 has a detector 3 that detects secondary particles (secondary or reflected electrons, secondary charged particles such as ions, photons, X-rays, etc.) generated by irradiation with the primary charged particle beam. In the second enclosure 121, i.e., in the space where the sample is placed, there is installed a detector 151 capable of detecting secondary particles as will be discussed later.

The charged particle microscope of the first embodiment has the control system that includes a computer 35 used by an apparatus user, a master control unit 36 connected with the computer 35 to conduct communications, and a slave control unit 37 that controls an evacuation system and a charged particle optical system, among others, under instructions from the master control unit 36. The computer 35 has a monitor that displays an apparatus operation screen (GUI) and input means such as a keyboard and a mouse for making entries into the operation screen. The master control unit 36, slave control unit 37 and computer 35 are interconnected by communication lines 43 and 44.

The slave control unit 37 is a unit that sends and receives control signals for controlling the vacuum pump 4, charged particle source 8, and optical lens 1. Also, the slave control unit 37 converts the output signal from the detector 3 into a digital image signal before transmitting the signal to the master control unit 36. In FIG. 1, the output signals from the detectors 3 and 151 are connected to the slave control unit 37 via signal amplifiers 153 and 154 such as preamplifiers. The signal amplifiers may be omitted if unnecessary.

In the master control unit 36 and slave control unit 37, both analog and digital circuits may coexist. The master control unit 36 and slave control unit 37 may alternatively be unified into a single unit. It should be noted that the structure of the control system shown in FIG. 1 is only an example and that variations of the control units, valves, vacuum pumps, communication wiring, etc., fall within the scope of the charged particle beam microscope of the first embodiment as long as such variations fulfill the functions intended by this embodiment.

The first enclosure 7 is connected with vacuum piping 16 of which one end is coupled to the vacuum pump 4, so that the inside of the first enclosure 7 is kept in a vacuum state. Also, the first enclosure 7 has a leak valve 14 that exposes the enclosure interior to the atmosphere. At the time of maintenance, the leak valve 14 can expose the inside of the first enclosure 7 to the atmosphere. Installation of the leak valve 14 is optional. There may be two or more leak values 14 installed. Installation of the leak valve 14 on the first enclosure 7 is not limited to the location shown in FIG. 1; the valve may be located elsewhere on the first enclosure 7. Furthermore, the first enclosure 7 has on its side an opening through which the second enclosure 121 is inserted.

The second enclosure 121 is composed of a cuboid-shaped main unit 131 and a matching unit 132. At least one side of the main unit 131 as the cuboid is an open side 9, as will be discussed later. Except for one of the sides of the cuboid-shaped main unit 131 to which a diaphragm holding member 155 is attached, the sides of the main unit 131 may be formed by the walls of the second enclosure 121. Alternatively, the second enclosure 121 may be devoid of its own walls. Instead, the second enclosure 121 may be formed by the sidewalls of the first enclosure 7 into which the second enclosure 121 is built. The second enclosure 121 is positionally fixed to the sidewalls or inner wall surfaces of the first enclosure 7 or to the charged particle optical tube. The main unit 131 is inserted into the first enclosure 7 through the above-mentioned opening. In its built-in state, the main unit 131 has the function of storing the sample 6 to be observed. The matching unit 132 has a matching surface against the outer wall surface of the side on which the opening of the first enclosure 7 is provided, and is fixed to that outer wall surface by means of a vacuum sealing member 126. In this manner, the second enclosure 121 as a whole is fit into the first enclosure 7. The above-mentioned opening is formed most simply by utilizing the opening that is intrinsically provided to the vacuum sample chamber of the charged particle microscope and is used for bringing in and out the sample. That is, the second enclosure 121 may be manufactured in a manner conforming to the size of the existing hole of which the circumference may be furnished with the vacuum sealing member 126. As a result, the effort to remodel the apparatus can be minimized. Also, the second enclosure 121 may be detached from the first enclosure 7.

The upper surface side of the second enclosure 121 is provided with a diaphragm 10 that is positioned immediately under the charged particle optical tube 2 when the entire second enclosure 121 is fit into the first enclosure 7. Also, the upper part of the second enclosure 121 is furnished with the detector 151. The diaphragm 10 allows the primary charged particle beam discharged from the lower end of the charged particle optical tube 2 to permeate or pass therethrough. Past the diaphragm 10, the primary charged particle beam ultimately reaches the sample 6.

In the past, the sample was held in a liquid-filled space inside of the diaphragm. Once the sample was observed in the atmosphere, the sample became wet so that it was very difficult to observe the sample in the same state in both the air atmosphere and the high-vacuum atmosphere. Another problem was that since the diaphragm was always in contact with liquid, the diaphragm was highly liable to break. By contrast, the method of the first embodiment involves keeping the sample 6 out of contact with the diaphragm 10 so that the sample can be observed in both the high-vacuum atmosphere and the air atmosphere without changing its state. Furthermore, the diaphragm is less likely to break because the sample is not placed thereon.

Having reached the sample 6, the charged particle beam causes secondary particles such as reflected or permeated charged particles to be discharged from the surface or from inside of the sample. The detector 3 or 151 detects the secondary particles. The detector 3 is located in a space above the diaphragm to which the charged particles are emitted. The detector 151 is positioned approximately on the same plane as the lower side surface of the diaphragm.

The detectors 3 and 151 are each a detecting element capable of detecting charged particle beams emitted with several to tens of KeV of energy. The detecting elements may also be provided with signal amplifying means. In view of the requirements of the apparatus configuration, the detecting elements should preferably be shaped thin and flat. For example, the detecting elements may be semiconductor detectors made of a semiconductor material such as silicon, or may be scintillators capable of converting charged particle signals into light internally or by use of their glass surfaces.

Where the charged particle beam is an electron beam, the diaphragm 10 needs to be thin enough to let the electron beam permeate, typically several nm to less than 20 μm in thickness. In place of the diaphragm, there may be provided an aperture member having a hole that lets the primary charged particle beam pass therethrough. In this case, the hole should preferably be 1 mm² or less in area in view of the requirement that a commonly available vacuum pump be capable of differential evacuation. Where the charged particle beam is an ion beam, an aperture with an area of less than about 1 mm² is used because the penetration is difficult to achieve without damaging the diaphragm. A dashed line in FIG. 1 indicates the optical axis of the primary charged particle beam. The charged particle optical tube 2 and the diaphragm 10 are axially aligned with the primary charged particle beam. The distance between the sample 6 and the diaphragm 10 is adjusted using a platform 17 of a suitable height.

As shown in FIG. 1, one side of the second enclosure 121 is the open side 9 communicating with the air atmosphere and large enough to at least bring in and out the sample therethrough. The sample 6 housed inside the second enclosure 121 (a space to the right of the dotted line in FIG. 1, called the second space hereunder) is in an atmospheric state during observation. Incidentally, although FIG. 1 is a sectional view of the apparatus in parallel with the optical axis and shows only one open side 9, there may be more than one open side 9 for the second enclosure 121 as long as the opening is vacuum-sealed by those sides of the first enclosure in the depth and at the front of FIG. 1. There need only be at least one open side where the second enclosure 121 is built into the first enclosure 7. Meanwhile, the vacuum pump 4 is connected to the first enclosure 7 so that a closed space (called the first space hereunder) formed by the inner wall surfaces of the first enclosure 7, the outer wall surfaces of the second enclosure, and the diaphragm 10 can be evacuated. In the first embodiment, the diaphragm is arranged so that the pressure of the second space is kept higher than the pressure of the first space. This arrangement isolates the second space by pressure. That is, while the diaphragm 10 keeps the first space 11 in a high-vacuum state, the second space 12 is maintained in a gas atmosphere at atmospheric pressure or at a pressure approximately equal thereto. This allows the first embodiment to keep the charged particle optical tube 2 and the detector 3 in the vacuum state during operation of the apparatus while maintaining the sample 6 at atmospheric pressure for example.

According to the existing techniques such as the environmental cell that can locally maintain an air atmosphere, it is possible to observe the sample in an air or gas atmosphere only if the sample is small enough to be inserted into the cell. Larger samples cannot be observed in the air/gas atmosphere. Moreover, in the case of the environmental cell, observing different samples requires performing a troublesome sample replacement procedure. That is, the environmental cell is required to be extracted from the vacuum sample chamber of the SEM and, with the current sample replaced by a new sample, again brought into the vacuum sample chamber. By contrast, according to the method of the first embodiment, one side of the second enclosure 121 is left open so that the sample 6 as large as a semiconductor wafer can be placed in the second space 12 constituting an extensive atmospheric pressure space for observation under atmospheric pressure. In particular, the second enclosure of the first embodiment can be easily made large in size because it is configured to be inserted laterally into the sample chamber. A sample too large to be placed into the environmental cell can thus be observed. Furthermore, the second enclosure 121 has the open side that allows samples to be switched easily between the inside and the outside of the second space 12 during observation.

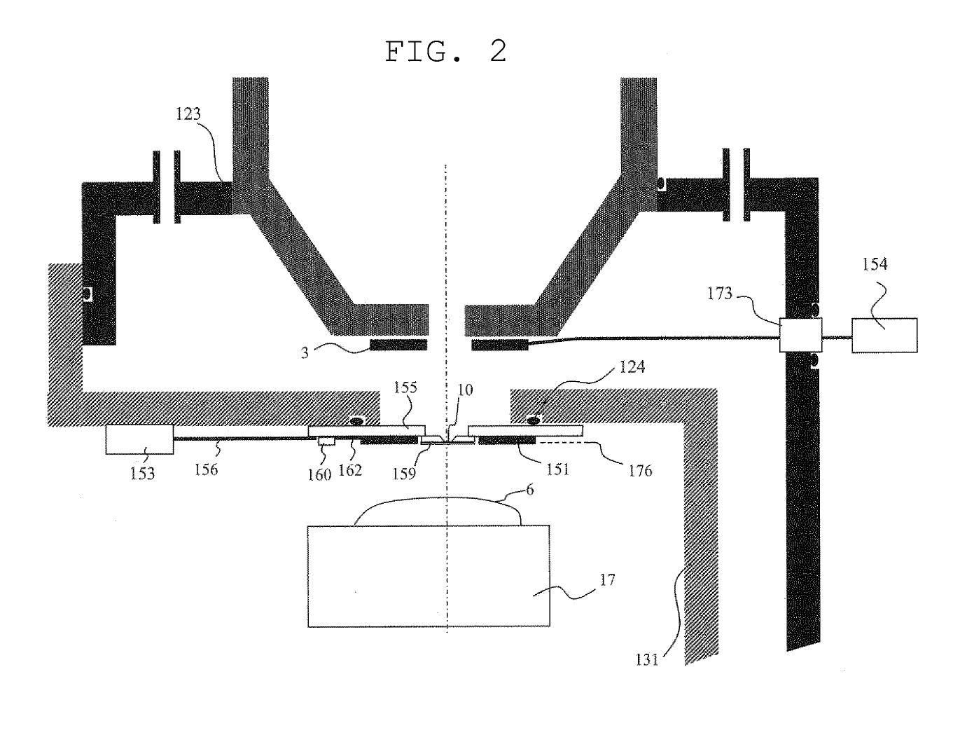

FIG. 2 is a detail plan showing the vicinities of the detector 3, diaphragm 10, sample 6, and detector 151. In FIG. 2, the diaphragm 10 and detector 151 are located on the diaphragm holding member 155 and opposite to the sample. That means the detector 151 is positioned in the same pressure atmosphere in which the sample is placed. On the other hand, the detector 3 is located in the space opposite to the one in which the sample 6 is placed across the diaphragm 10. The detector 3 is thus found in the vacuum state. Whereas two detectors 3 and 151 are shown installed in FIG. 2, there may be one detector, two detectors, or other detectors additionally configured. The diaphragm 10 is formed or deposited on the diaphragm holding member 155. A base 159 fitted with the diaphragm 10 is mounted on the diaphragm holding member 155. Although not shown, the base 159 furnished with the diaphragm 10 and the diaphragm holding member 155 are bonded or snugly fit together with an adhesive or double-sided tape capable of vacuum sealing.

The base 159 furnished with the diaphragm 10 is detachable from the diaphragm holding member 155. Where the base 159 fitted with the diaphragm 10 is in place, the diaphragm holding member 155 is allowed to be detached. If the diaphragm 10 is damaged upon contact with the sample 6 for example, the entire diaphragm holding member 155 can be removed from the apparatus for easy replacement of the diaphragm 10. Although not shown, the diaphragm holding member 155 may be connected to the second enclosure 121 with screws or the like.

The detector 151 is installed in a manner surrounding the diaphragm 10. A signal detected by the detector 151 is output to the signal amplifier 153 via a signal line 156. In FIG. 2, the signal amplifier 153 is arranged inside the second enclosure 121. Because the detector 151 generally outputs feeble signals, the arrangement of the signal amplifier being positioned close to the detector 151 minimizes the disturbance affecting the signals from the detector. If the disturbance noise is negligible, the signal amplifier 153 may be installed outside the second enclosure 121.

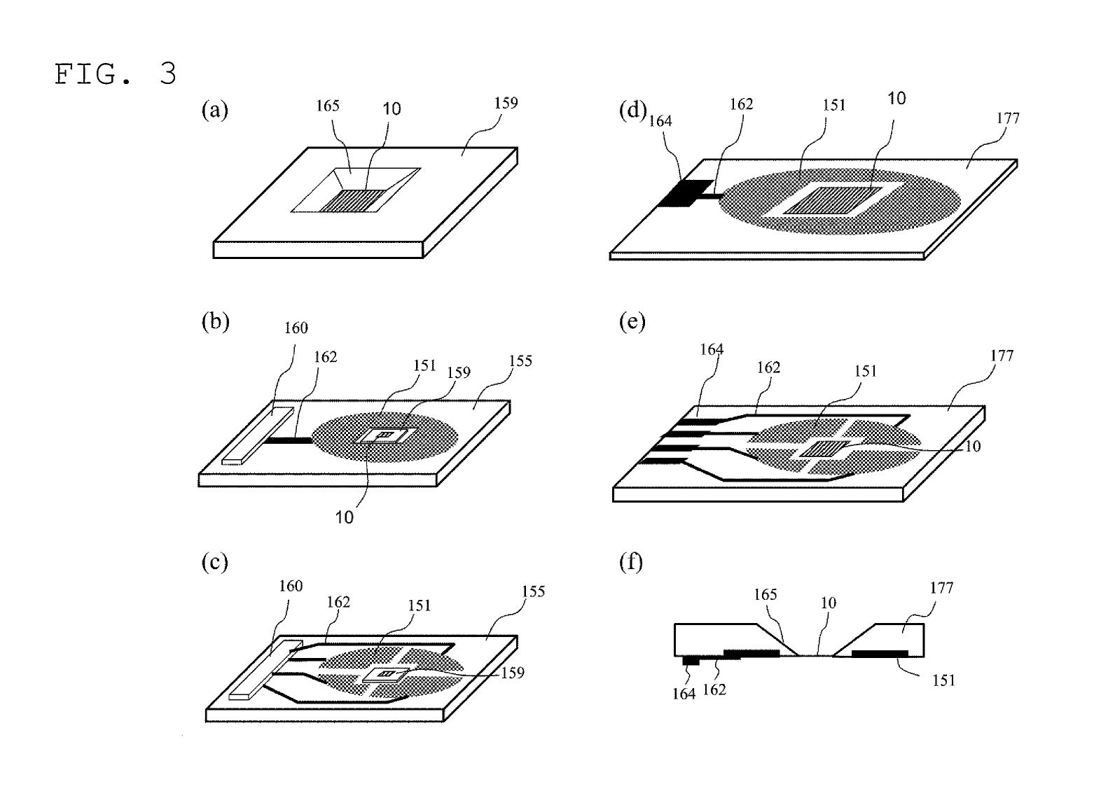

FIG. 3(a) shows the structure surrounding the diaphragm 10 and detector 151. The diaphragm 10 is mounted on the base 159. The diaphragm 10 is made of a carbon material, an organic material, silicon nitride, silicon carbide, or silicon oxide. The base 159 is a member made of silicon for example, and has a tapered hole 165 formed typically by wet etching as illustrated. The diaphragm 10 is positioned at the bottom as shown in FIG. 3(a). Alternatively, the base 159 may be a metal mesh mounted with the diaphragm. The diaphragm is about several nm to tens of μm in thickness.

FIGS. 3(b) and 3(c) show how the base 159, positioned on the diaphragm holding member 155, is fitted with the diaphragm 10 and the detector 151 capable of detecting the charged particle beam. These drawings are perspective views seen from the side of the sample 6. The detector 151 is installed in a manner surrounding the diaphragm. Although not shown, the diaphragm holding member 155 equipped with the detector 151 and the base 159 fitted with the diaphragm 10 are bonded together with an adhesive or double-sided tape capable of vacuum sealing. A sectional view of this assembly is as shown in FIG. 2. The diaphragm holding member 155 has a hole that lets the charged particle beam pass therethrough. The diaphragm 10 is located close to this hole. Although the detector 151 is shown to be round in shape in the drawings, the detector 151 may also have a different shape such as a rectangle.

Here, the surface of the diaphragm 10 and the detecting surface of the detector 151 should preferably be positioned approximately on the same plane. For example, a dotted line 176 in FIG. 2 indicates the surface of the detector and that of the diaphragm. This arrangement makes it possible to position the sample as close to both the diaphragm 10 and the detector 151 as possible during the approach of the sample to the diaphragm.

The detector 151 is a semiconductor detection element made of silicon, for example. Upon receipt of the charged particle beam or the like, the semiconductor detection element amplifies signals and generates a current. This current is output to a connector 160 via a signal line 162.

The detector 151 may be provided not in one piece but in multiple parts (e.g., 4 parts) as shown in FIG. 3(c). If the detecting surface of the detector is too wide, the existing capacity component (capacitance) can narrow the signal band that may be detected by the detector. If it is desired to widen the signal band, the detector may preferably be divided into multiple (e.g., 4) parts to reduce the capacitance component.

FIG. 3(d) shows an example in which the diaphragm holding base and the detector are integrally formed. If the base 159 and the detector 151 are both made of silicon to constitute a semiconductor detector, it is possible to simultaneously manufacture, during the semiconductor process, a holding stand 177 fitted with the diaphragm 10 and the detecting element 151. A signal detected by the detector 151 is output to a pad 164 made of a metal via the signal line 162. The pad 164 may be connected to the signal amplifier 153 via a wire bonding or connector arrangement. As shown in FIG. 3(e), the detector 151 may be provided in multiple parts (e.g., 4 parts).

FIG. 3(f) is a sectional view of the setups in FIGS. 3(d) and 3(e). In FIG. 3(f), the lower part is on the sample side. On the vacuum side (upper part in the drawing) is the tapered hole 165 designed to boost the efficiency of the detector 3 in detecting and acquiring signals. The detector 151 is installed on the surface of or inside the holding stand 177. Where the detecting part is located inside the holding stand, it is easy to form the surface of the diaphragm and that of the detector approximately on the same plane.

The detector 151 may also be a scintillator that converts the charged particle beam to light. The scintillator first converts the charged particle beam to light. In this case, the signal line 162 is not an electrical signal line but a light wave channel, and the connector 160 is an optical transmission connector. Also, the detector 151 may not be limited to a connector that detects the charged particle beam such as ions and electrons but may be a connector that detects photons or X-rays discharged from the sample. As another alternative, the detector 151 may be a multi-channel plate, an ionization chamber, or some other detector. As long as it satisfies the functions intended by the first embodiment, the detector falls within the scope of the charged particle beam microscope of the first embodiment.

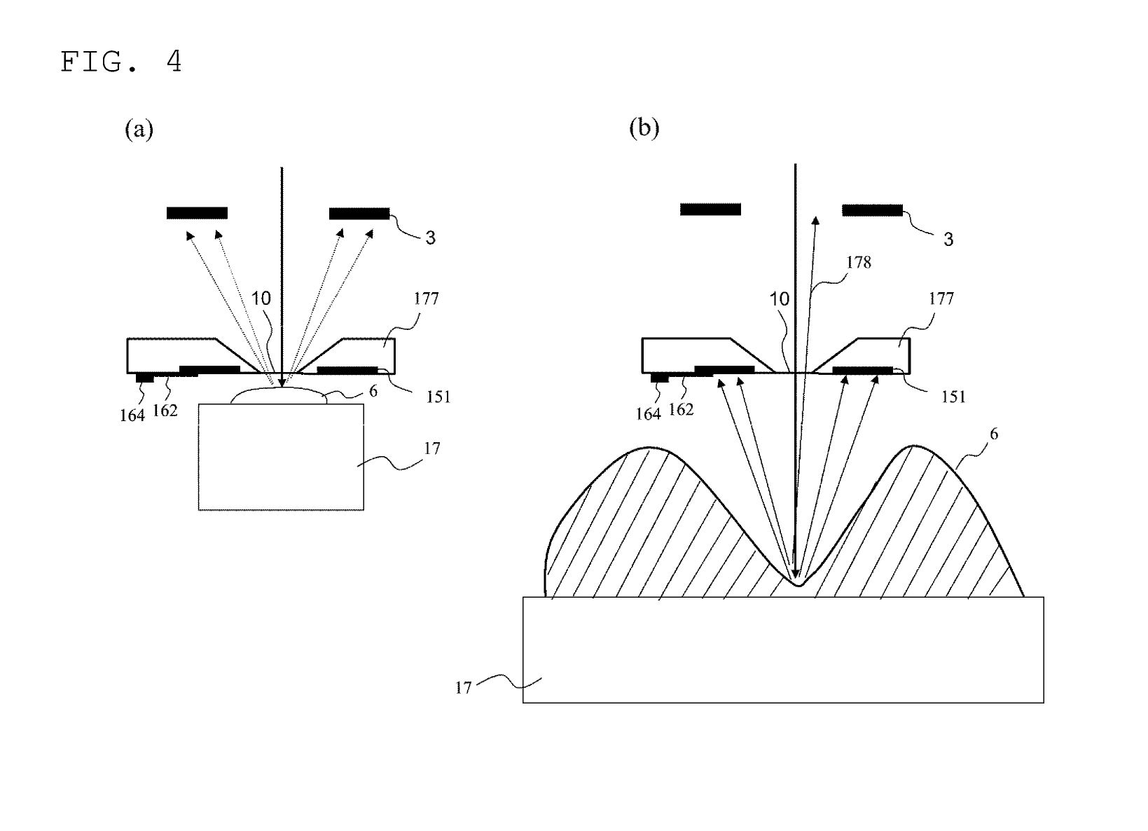

Explained next with reference to FIG. 4 is how to use the detectors 3 and 151.

FIG. 4(a) shows how the diaphragm 10 and the sample 6 come close to each other. Where the diaphragm 10 and the sample 6 are positioned close to each other, the secondary particles generated by the charged particle beam being emitted to the sample can reach the detector 3. Whereas the clearance between the diaphragm 10 and the sample 6 is in an atmospheric state, if it is desired to minimize the scattering of the charged particle beam, i.e., if it is desired to minimize the spot diameter of the charged particle beam in order to improve resolution, then bringing the sample 6 close to the diaphragm 10 in this manner is effective.

On the other hand, if it is desired to observe a sample with a prominently uneven surface such as one shown in FIG. 4(b), the detector 151 may be used for observation. In this case, the secondary particles discharged from the sample can be detected by the detector 151. That is, where there is a long distance between the diaphragm and that part of the sample to which the charged particle beam is emitted, it is difficult for the detector 3 to detect charged particles 178 returning from the diaphragm as a signal. Thus the detector 151 located closer to the diaphragm 10 can observe the uneven sample.

It may be determined to use one or both of the detectors depending on the distance between the diaphragm and the sample and control the ON/OFF of each of the detectors accordingly. Alternatively, both detectors may always be used to detect secondary particles.

It may seem that the detector 151 is not necessary if the diaphragm 10 has a sufficiently wide area. However, the diaphragm is made thin enough to let the charged particle beam permeate therethrough, so that enlarging the area of the diaphragm is extremely difficult. For this reason, when a sample with an uneven surface is to be observed, it is preferred to position the detector 151 in the vicinity of the diaphragm 10.

As explained above, the first embodiment brings about a charged particle microscope capable of observing uneven samples at atmospheric pressure.

### Second Embodiment

The second embodiment is explained below as another application of the present invention to the charged particle microscope. Specific examples of the charged particle microscope include scanning electron microscope and ion microscopes. In the ensuing paragraphs, the portions of the second embodiment similar to those of the first embodiment will not be discussed further.

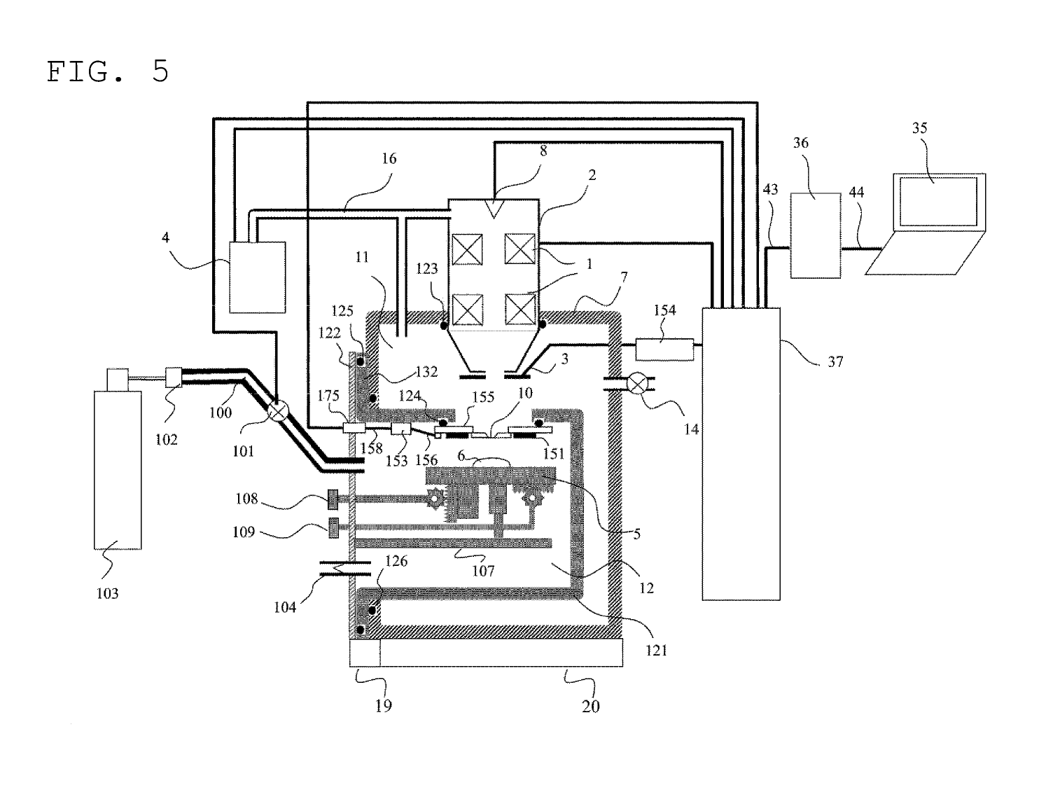

FIG. 5 is an overall block diagram of a charged particle microscope as the second embodiment. As with the first embodiment, the charged particle microscope of the second embodiment is made up of a charged particle optical tube 2, a first enclosure (vacuum chamber) 7 that supports the charged particle optical tube against an apparatus installation surface, a second enclosure 121 (attachment) inserted into the first enclosure 7 when used, and a control system. The operations and functions of these components as well as the elements added thereto are substantially the same as those of the first embodiment and thus will not be discussed further in detail.

The diaphragm holding member 155 is detachably fixed to the lower surface side of the ceiling board of the second enclosure 121 with a vacuum sealing member interposed therebetween. The diaphragm 10 is made as thin as several nm to tens of μm for allowing the electron beam to permeate therethrough. Being formed very thin, the diaphragm 10 can break over time or during preparation of observation. Also, the diaphragm 10 is so thin that it is very difficult to handle directly. Because the second embodiment allows the diaphragm 10 to be handled not directly but by means of the diaphragm holding member 155, it is appreciably easy to deal with the diaphragm 10 (especially its replacement). That is, when the diaphragm 10 is broken, it may be replaced altogether with the diaphragm holding member 155. In case only the diaphragm 10 needs to be replaced, the diaphragm holding member 155 may be first detached from the apparatus and then the diaphragm 10 may be replaced outside the apparatus. As with the first embodiment, an aperture member having a hole about 1 mm² or less in area may alternatively substitute for the diaphragm. And as explained above with reference to FIGS. 1 and 2, a detector 151 is provided in the vicinity of the diaphragm 10.

A detection signal from the detector 151 is sent to a slave control unit 37 via a hermetic connector 175 attached to a cover part 122 past a signal amplifier 153. Since a second space 12 inside the second enclosure may be brought into a vacuum state as will be discussed later, the hermetic connector 175 should preferably be a vacuum-sealed hermetic connector capable of maintaining the vacuum region inside. Although the signal amplifier 153 is shown installed in the second space 12 in the drawing, the signal amplifier 153 may alternatively be installed outside (in the air atmosphere) or in a first space as a vacuum space.

In the case of the charged particle microscope as the second embodiment, the open side of the second enclosure 121 can be covered with the cover part 122, so that various functions may be implemented. These functions are explained below.

The charged particle microscope of the second embodiment has the function of feeding a shift gas other than the air into the second enclosure. The charged particle beam discharged from the lower end of the charged particle optical tube 2 passes through the first space 11 maintained in a high-vacuum state to permeate the diaphragm 10 shown in FIG. 5, before entering the second space 12 kept at atmospheric pressure or at a slightly negative pressure (lower than the pressure of the first space). However, the mean free path of the charged particle beam is shortened in a space with a low degree of vacuum because the particles are scattered by gas molecules therein. That is, if there is a long distance between the diaphragm 10 and the sample 6, the charged particle beam or secondary particles such as secondary electrons, reflected electrons or transmission electrons generated by the emitted charged particle beam fail to reach the sample or detectors 3 and 151. Meanwhile, the scattering probability of the charged particle beam is proportional to the mass number of gas molecules. Thus if the second space 12 is filled with gas molecules having a smaller mass number than the air, the scattering probability of the charged particle beam declines and the charged particle beam can reach the sample. The second space need not be entirely filled with a shift gas; at least the air along the passing path of the electron beam in the second space need only be replaced with the shift gas. Varieties of the shift gas include nitrogen and water vapor, which are lighter than the air and prove to be effective in improving the S/N ratio of images. However, a gas with a smaller mass such as helium gas or hydrogen gas is more effective in improving the image S/N ratio.

For the above reasons, the charged particle microscope of the second embodiment has the cover part 122 having an attaching part (gas introduction part) for a gas feed pipe 100. The gas feed pipe 100 is coupled to a gas cylinder 103 via a coupling portion 102, which allows a shift gas to be introduced into the second space 12. Halfway along the gas feed pipe 100, there is provided a gas control valve 101 that controls the flow rate of the shift gas flowing through the pipe. For control purposes, a signal line is extended from the gas control valve 101 to the slave control unit 37. The apparatus user can control the flow rate of the shift gas through an operation screen displayed on the monitor of a computer 35.

Since the shift gas is a light element gas, it tends to stay in the upper region of the second space 12; it is difficult to fill the lower region of the second space 12 with the shift gas. This bottleneck may be bypassed by providing the cover part 122 with an opening for communicating the inside and the outside of the second space at a location lower than the mounting position of the gas feed pipe 100. In FIG. 5, for example, the opening is provided in the location to which a pressure regulating valve 104 is attached. This arrangement causes the atmospheric gas to be discharged from the lower side opening under pressure of the light element gas introduced through the gas introduction part, so that the second enclosure is filled with the gas efficiently. Incidentally, this opening may double as a rough exhaust port, to be discussed later.

A vacuum evacuation port may be provided on the second enclosure 121 or cover part 122 to once evacuate the second enclosure 121 so that a slightly negative pressure is generated therein. In this case, low-vacuum evacuation instead of high-vacuum evacuation is sufficient because the atmospheric gas components residing inside the second enclosure need only be reduced to a predetermined level or lower. Following low-vacuum evacuation, gas may be introduced through the gas feed pipe 100. The degree of vacuum involved is from 10⁵ Pa to 10³ Pa or thereabout. If gas is not to be introduced, the gas cylinder 103 may be replaced with a vacuum pump to generate a slightly negative pressure inside.

In the ordinary, so-called low-vacuum scanning electron microscope, the electron beam column communicates with the sample chamber. It follows that lowering the degree of vacuum in the sample chamber close to atmospheric pressure entails varying the pressure inside the electron beam column correspondingly. It has been difficult to control the sample chamber to pressures ranging from about 10⁵ Pa (atmospheric pressure) to about 10³ Pa. According to the second embodiment, by contrast, the diaphragm isolates the second space from the first space, so that the pressure and type of the gas in the second space enclosed by the second enclosure 121 and cover part 122 can be freely controlled. This makes it possible to control the sample chamber to pressures ranging from about 10⁵ Pa (atmospheric pressure) to about 10³ Pa—something that has been difficult to achieve in the past. Moreover, the state of the sample can be observed not only at atmospheric pressure (about 10⁵ Pa) but also under continuously varying pressures close thereto.

However, if the sample is a biological sample or the like that contains moisture, the contained moisture evaporates once the sample is placed in a vacuum state so that the state of the sample is changed. In this case, a shift gas should preferably be introduced directly from the air atmosphere as explained above. When the above-mentioned opening is closed with the cover part following introduction of the shift gas, the shift gas may be effectively contained within the second space 12.

If a three-way valve is attached to the location of the above-mentioned opening, this opening may double as a rough exhaust port and an air leak exhaust port. Specifically, one port of the three-way valve is coupled to the cover part 122, another port to a vacuum pump for rough exhaust, and another port to a leak valve. The dual-purpose exhaust port mentioned above can be implemented in this manner.

In place of the opening above, the pressure regulating valve 104 may be provided. The pressure regulating valve 104 has the function of automatically opening if the pressure inside the second enclosure 121 becomes higher than atmospheric pressure. If the internal pressure gets higher than atmospheric pressure during introduction of a light element gas, the pressure regulating valve having this function automatically opens to release the atmospheric gas components such as nitrogen and oxygen into the outside of the apparatus and thereby fill the inside of the apparatus with the light element gas. Incidentally, the gas cylinder 103 shown in the drawing may be attached to the charged particle microscope either during manufacturing or later by the apparatus user.

How to adjust the position of the sample 6 is explained next. The charged particle microscope of the second embodiment has a sample stage 5 as a means for moving the field of observation. The sample stage 5 is provided with an X-Y drive mechanism for movement in the plane direction and a Z-axis drive mechanism for movement in the height direction. The cover part 122 is furnished with a support plate 107 that serves as a base plate for supporting the sample stage 5. The sample stage 5 is fixed to the support plate 107. The support plate 107 is installed in such a manner as to extend toward the opposite surface of second enclosure 121 from the cover part 122 and into the inside of the second enclosure 121. Support shafts extend from the Z-axis drive mechanism and X-Y drive mechanism, each of the shafts being coupled with operation knobs 108 and 109. By manipulating the operation knobs 108 and 109, the apparatus user adjusts the position of the sample 6 inside the second enclosure 121.

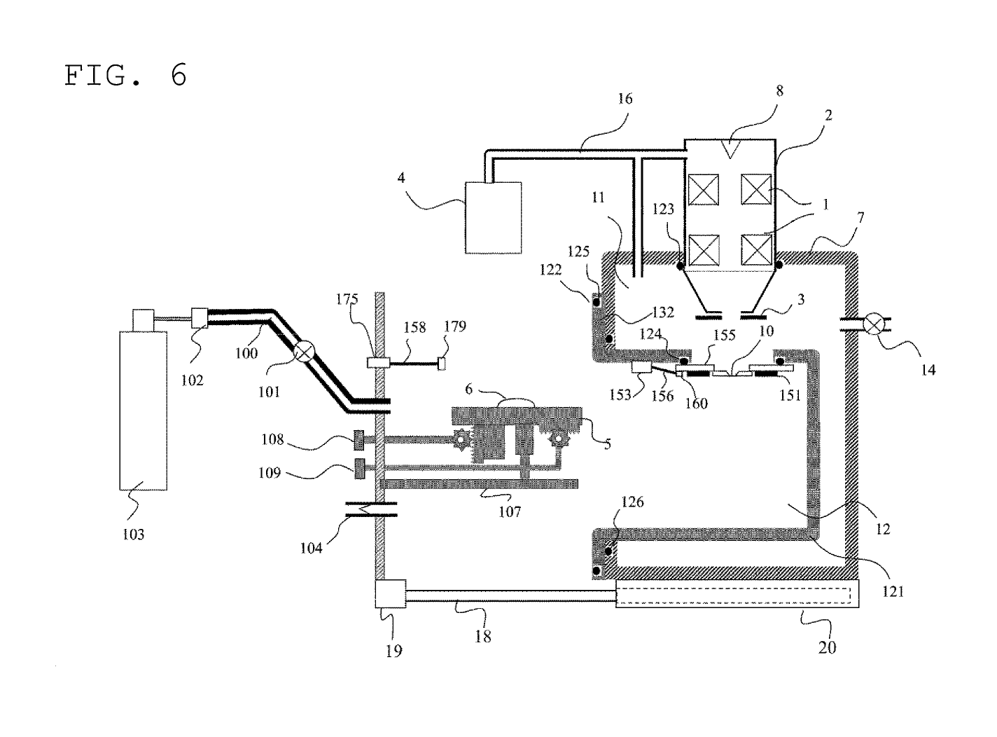

The mechanisms for replacing the sample 6 are explained next. The charged particle microscope of the second embodiment has a cover part support member 19 and a base plate 20 installed under the bottom of the first enclosure 7 and under the lower surface of the cover part 122, respectively. The cover part 122 is detachably fixed to the second enclosure 121 with a vacuum sealing member 125 interposed therebetween. The cover part support member 19 is also fixed detachably to the base plate 20. As shown in FIG. 6, the cover part 122 and cover part support member 19 can be detached as a whole from the second enclosure 121. In the drawing, electrical wiring is not shown.

The base plate 20 is provided with a support rod 18 for use as a guide upon removal. In the normal state of observation, the support rod 18 is housed in a storage part of the base plate 20. The support rod 18 is structured to extend in the direction in which the cover part 122 is drawn out for removal. Also, the support rod 18 is fixed to the cover part support member 19 so that when the cover part 122 is removed from the second enclosure 121, the cover part 122 will not be completely detached from the body of the charged particle microscope. This arrangement is intended to prevent the sample stage 5 or the sample 6 from falling.

FIG. 6 shows how a signal line 158 is detached from the signal amplifier 153 when the cover part 122 is drawn out in the direction of removal. For example, the signal line 158 may be electrically attached and detached to and from the signal amplifier 153 by means of a connector 179 or the like used therebetween. If the signal line 158 is sufficiently long, there is no need to detach it from the signal amplifier 153. The signal line 158 may also be an extendable wire. The portion of the signal line to be detached may be between the signal line 156 and the output connector 160 coming from the detector 151 or on the side of the hermetic connector 175. Although not shown, if the hermetic connector 175 for outputting the output signal from the signal amplifier 153 is not attached to the cover part 122 but coupled to the first enclosure 7 or to the second enclosure 121, then the above electrical connection section need not be detached and attached every time the sample is replaced.

Where to set up the signal amplifiers and the output signal lines extending therefrom, and how to wire and how to attach and detach these components will fall within the scope of the charged particle microscope of the second embodiment as long as these arrangements and methods satisfy the functions intended by the second embodiment.

When the sample is to be brought into the second enclosure 121, the operation knob for the Z-axis of the sample stage 5 is first operated to move the sample 6 away from the diaphragm 10. The pressure regulating valve 104 is then opened to expose the inside of the second enclosure to the atmosphere. Thereafter, following the verification that the inside of the second enclosure is neither in a negative pressure state nor in an inordinately pressured state, the cover part 122 is drawn out to the opposite side of the apparatus body. If the signal amplifier 153 is connected by wire with the hermetic connector 175, the wiring is detached as needed. This brings about the state in which the sample 6 can be replaced. After the sample is replaced, the signal amplifier 153 is electrically reconnected with the hermetic connector 175 as needed; the cover part 122 is pressed into the second enclosure 121; the cover part 122 is fixed to the matching unit 132 using a fastening member, not shown; and a shift gas is introduced as needed. The above operations may also be carried out while a high voltage is being applied to an optical lens 2 inside the charged particle optical tube 2 or while the charged particle beam is being discharged from the charged particle source 8. This means that the above operations can be performed while the charged particle optical tube 2 is allowed to operate continuously, with the first space kept in the vacuum state. The charged particle microscope of the second embodiment thus permits observation to be started quickly after the sample is replaced.

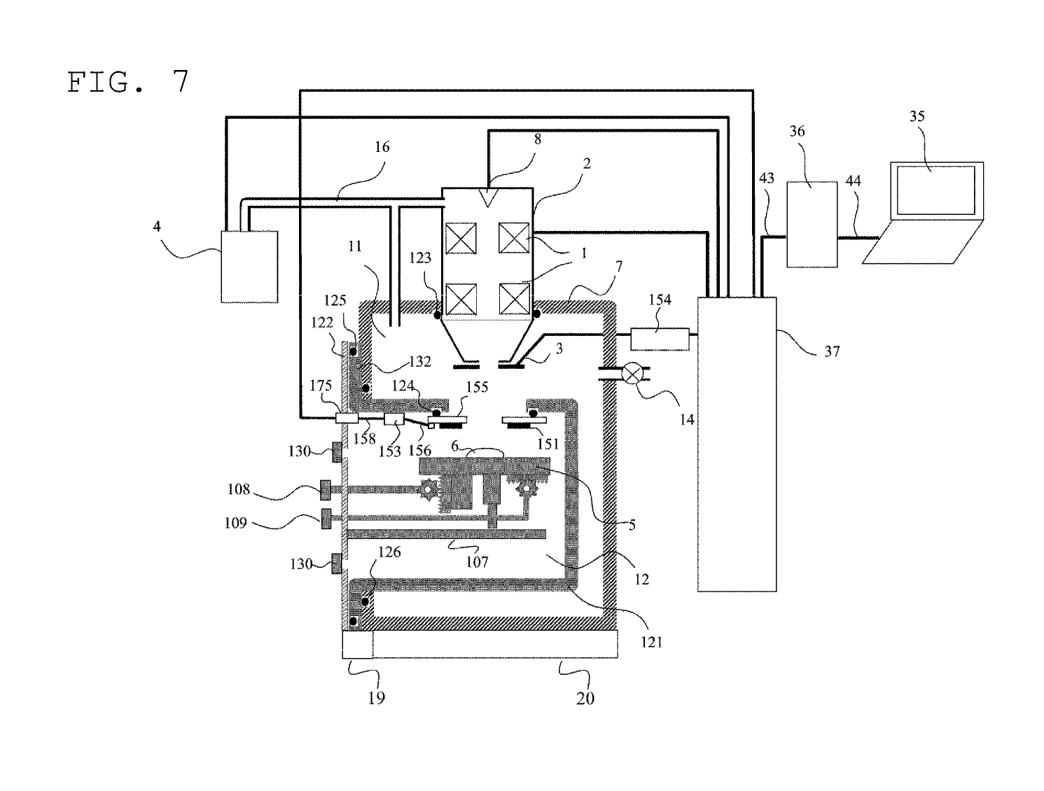

The charged particle microscope of the second embodiment may also be used as an ordinary high-vacuum SEM. FIG. 7 is an overall block diagram showing the charged particle microscope of the second embodiment used as a high-vacuum SEM. In FIG. 7, the control system is the same as that in FIG. 5 and is not shown. FIG. 7 shows a charged particle microscope in which, with the cover part 122 fixed to the second enclosure 121, the gas feed pipe 100 and pressure regulating valve 104 are detached from the cover part 122 and in which the mounting positions vacated by the gas feed pipe 100 and pressure regulating valve 104 are later covered with cover parts 130. After the diaphragm 10 and the diaphragm holding member 155 are detached from the second enclosure 121 by carrying out the above series of operations, the first space 11 can be connected with the second space 12, allowing the inside of the second enclosure to be evacuated with the vacuum pump 4. This in turn makes it possible to perform high-vacuum SEM observations with the second enclosure 121 kept attached.

As explained above, the second embodiment has the sample stage 5, sample stage operation knobs 108 and 109, gas feed pipe 100, and pressure regulating valve 104 attached altogether to the cover part 122. As a result, the apparatus user can remain facing the same side of the first enclosure while manipulating the operation knobs 108 and 109 or working to replace the sample or to attach and detach the gas feed pipe 100 and pressure regulating valve 104. It follows that, compared with the ordinary charged particle microscope in which the above-mentioned components are mounted in a scattered manner on various sides of the sample chamber, the second embodiment offers appreciably enhanced operability when the state for observation at atmospheric pressure is switched with the state for observation in a high vacuum.

In addition to the secondary electron detector and the reflected electron detector, there may be provided an X-ray detector and a photodetector capable of EDS analysis and fluorescence line observation. The X-ray detector and photodetector may be installed in either the first space 11 or the second space 12.

A voltage may be applied to the sample stage 5 and detector 151. Applying the voltage to the sample stage 5 and detector 151 gives high energy to the emission and transmission electrons emanating from the sample 6, which can increase the amount of signals and thereby improve the S/N ratio of images.

As described above, the second embodiment supplements the effects of the first embodiment by acting as a high-vacuum SEM capable of making observations in a gas atmosphere at atmospheric pressure or at a slightly negative pressure. Because the second embodiment permits observation by letting the shift gas be introduced, the charged particle microscope of the second embodiment permits acquisition of images with a higher S/N ratio than the charged particle microscope of the first embodiment.

Although the second embodiment has been explained above with emphasis on a structure intended for use as a desktop electron microscope, the second embodiment may also be applied to a large-scale charged particle microscope. Whereas the desktop electron microscope has the entire apparatus or its charged particle optical tube supported by an enclosure on an apparatus installation surface, the large-scale charged particle microscope need only have the entire apparatus placed on a frame. Thus when the first enclosure 7 is placed on the frame, the structure discussed above in connection with the second embodiment can be applied unmodified to the large-scale charged particle microscope.

### Third Embodiment

The third embodiment is explained below in conjunction with a structure in which the cover part 122 is removed from the apparatus structure shown in FIG. 5. Those portions of the third embodiment which are similar to those of the first and the second embodiments will not be explained hereunder.

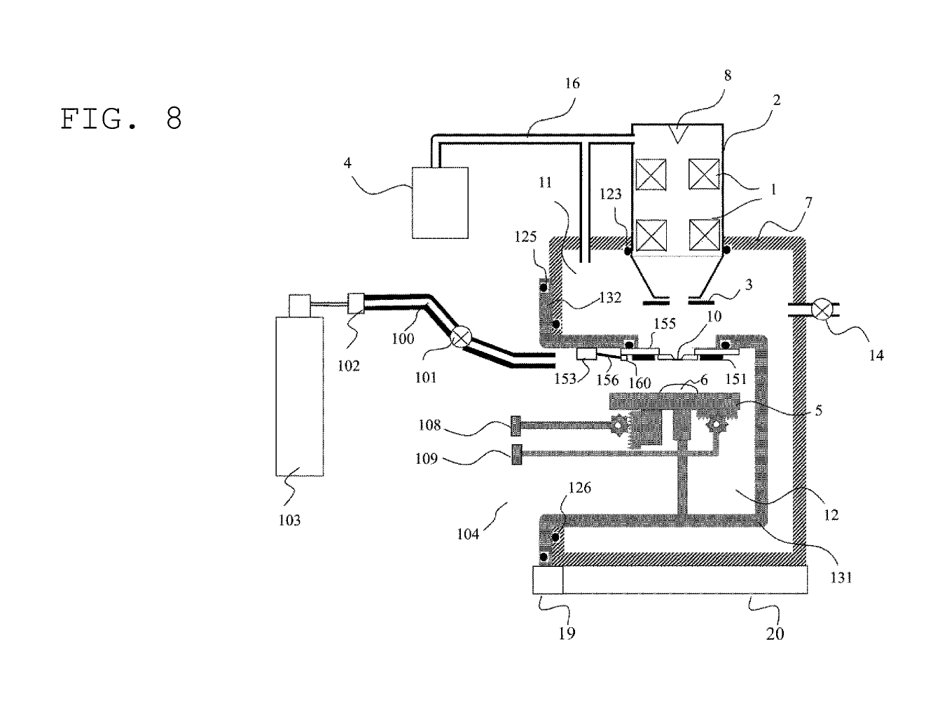

FIG. 8 shows an overall structure of a charged particle microscope as the third embodiment. The control system is the same as that of the second embodiment and is not shown. Only key components of the apparatus are illustrated in the drawing.

In the structure shown in FIG. 8, the sample stage 5 is fixed directly to the bottom of the second enclosure 121. The gas feed pipe 100 may or may not be fixed to the second enclosure 121. Because this structure allows the sample to protrude from the apparatus, the third embodiment makes it possible to observe a sample larger than on the second embodiment structured to have the cover part 122.

### Fourth Embodiment

The fourth embodiment is a variation of the apparatus structure shown in FIG. 5 where the second enclosure 121 is vacuum-sealed on the upper side of the first enclosure. In the ensuing paragraphs, those portions of the fourth embodiment which are similar to those of the first, the second, and the third embodiments will not be discussed further.

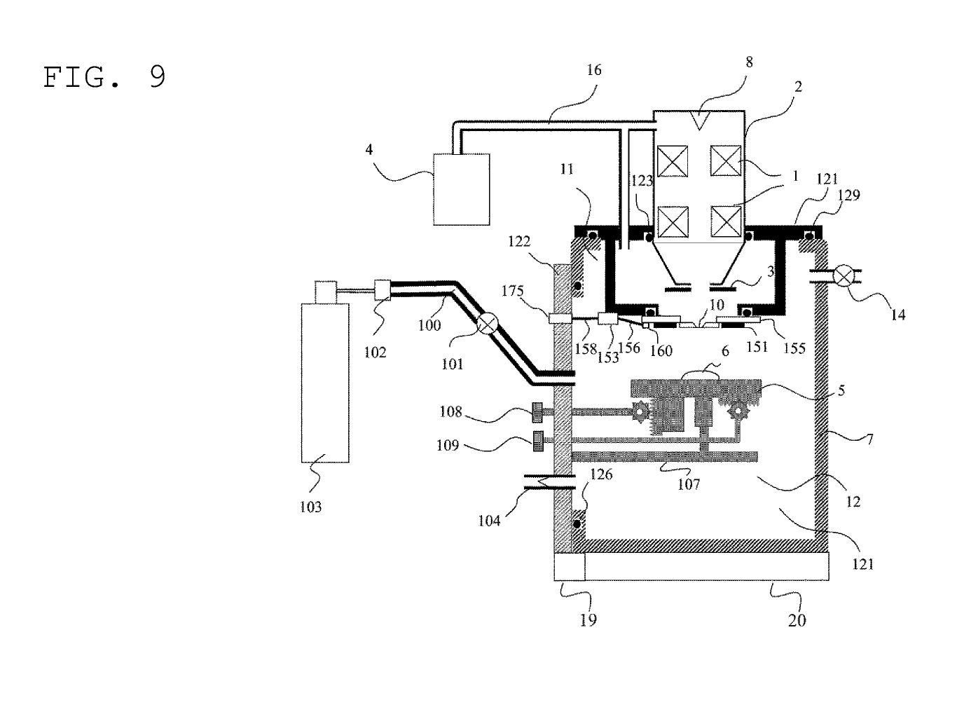

FIG. 9 shows an overall structure of a charged particle microscope as the fourth embodiment. As with the third embodiment, only key components of the apparatus are shown in FIG. 9. In this structure, a pan-shaped attachment (second enclosure 121) is fit into the first enclosure 7 from above. The charged particle optical tube 2 is further fit into this assembly from above. When mounted on the first enclosure, the attachment remains protruded into the cuboid-shaped first enclosure 7. In this state, a closed space (second space 12) formed by the inner wall surfaces of the first enclosure 7, the outer wall surfaces of the second enclosure, and the diaphragm 10 constitutes an atmospheric space, whereas the inside of the second enclosure 121 (first space 11) makes up an evacuated space.

The second enclosure 121 is vacuum-sealed to the charged particle optical tube 2 by means of the vacuum sealing member 123. Furthermore, the second enclosure 121 is vacuum-sealed to the first enclosure 7 using a vacuum sealing member 129. This structure provides a larger second space 12 than the structure shown in FIG. 5, so that the fourth embodiment allows a larger sample to be placed therein than the second embodiment.

The present invention is not limited to the embodiments discussed above and may also be implemented in diverse variations. The embodiments above have been explained as detailed examples helping this invention to be better understood. The present invention, when embodied, is not necessarily limited to any embodiment that includes all the structures described above. Part of the structure of one embodiment may be replaced with the structure of another embodiment. The structure of a given embodiment may be supplemented with the structure of another embodiment. Part of the structure of each embodiment may be supplemented with, emptied of, or replaced by another structure. The above-described structures, functions, processing units, and processing means may be implemented partially or entirely by hardware through integrated circuit design, for example. Also, the above-described structures and functions may be implemented by software in the form of programs which, when interpreted and executed by a processor, bring about the respective functionality.

The programs, tables, files, and other data for implementing the functions may be stored in storage devices such as memories, hard disks and SSD (Solid State Drive), or on recording media such as IC cards, SD cards and DVDs.

The illustrated control lines and data lines may not represent all control lines and data lines needed in the apparatus as a product. In practice, almost all structures may be considered to be interconnected.

### DESCRIPTION OF REFERENCE CHARACTERS

1: Optical lens
2: Charged particle optical tube
3: Detector
4: Vacuum pump
5: Sample stage
6: Sample
7: First enclosure
8: Charged particle source
9: Open side
10: Diaphragm
11: First space
12: Second space
14: Leak valve
16: Vacuum piping
18: Support rod
19: Board part support member
20: Base plate
35: Computer
36: Master control unit
37: Slave control unit
43, 44: Communication line
100: Gas feed pipe
101: Gas control valve
102: Coupling portion
103: Gas cylinder
104: Pressure regulating valve
105: Limiting member
106: Camera
107: Support plate
108, 109: Operation knob
121: Second enclosure
122, 130: Cover part
123, 124, 125, 126, 128, 129: Vacuum sealing member
131: Main unit
132: Matching unit
151: Detector
153, 154: Signal amplifier
155: Holding member
156, 157, 158: Signal line
159: Diaphragm holding base
160, 161: Connector
162, 163: Signal line
164: Metal pad
165: Tapered part
166: Detector holding base
173: Vacuum hermetic connector
174: Vacuum sealing part
175: Vacuum hermetic connector
176: Detector surface and diaphragm surface
177: Holding stand
178: Locus of secondary particles
179: Connector

1. A charged particle beam apparatus comprising:
a charged particle optical tube that irradiates a sample with a primary charged particle beam;
a vacuum pump that evacuates the inside of the charged particle optical tube;
a diaphragm arranged to separate a space in which the sample is placed from the charged particle optical tube, the diaphragm being detachable and allowing the primary charged particle beam to permeate or pass therethrough; and
a detector that detects secondary particles discharged from the sample being irradiated with the primary charged particle beam, wherein
the detector is installed in the space in which the sample is placed.

2. The charged particle beam apparatus according to claim 1, wherein the space in which the sample is placed has a higher pressure than the inside of the charged particle optical tube.

3. The charged particle beam apparatus according to claim 2, wherein the atmosphere of the space in which the sample is placed can be controlled to a pressure higher than 10³ Pa and lower than atmospheric pressure.

4. The charged particle beam apparatus according to claim 1, wherein a detector different from the stated detector is installed on the opposite side of the sample across the diaphragm.

5. The charged particle beam apparatus according to claim 4, wherein:
if the detector installed in the space where the sample is placed is at a first distance from the sample, the detector installed on the opposite side of the sample across the diaphragm is used to detect the secondary particles; and
if the detector installed in the space where the sample is placed is at a second distance from the sample, the second distance being longer than the first distance, the detector installed in the space where the sample is placed is used to detect the secondary particles.

6. The charged particle beam apparatus according to claim 1, wherein:
the detector is installed in an atmospheric pressure space; and
a detector different from the stated detector is installed in a vacuum space.

7. The charged particle beam apparatus according to claim 1, wherein the detector and the diaphragm are installed facing the surface of the sample irradiated with the charged particle beam.

8. The charged particle beam apparatus according to claim 1, wherein the diaphragm and a detecting surface of the detector are positioned on the same plane.

9. The charged particle beam apparatus according to claim 1, wherein the detector and the diaphragm are mounted on the same member.

10. The charged particle beam apparatus according to claim 9, wherein the member holding the detector and the diaphragm is made of a semiconductor material.

11. The charged particle beam apparatus according to claim 1, wherein the detector is formed by a plurality of detecting elements.

12. The charged particle beam apparatus according to claim 1, wherein a signal amplifier for amplifying a signal from the detector is installed in the space in which the sample is placed.

13. The charged particle beam apparatus according to claim 1, further comprising a gas inlet port through which the atmosphere at least in a space between the detector and the sample can be replaced with a gas other than air.

14. The charged particle beam apparatus according to claim 1, further comprising:
a first enclosure that supports the charged particle beam apparatus as a whole against an apparatus installation surface, the inside of the first enclosure being evacuated by a vacuum pump; and
a second enclosure of which the position is fixed to a side or an inner wall surface of the first enclosure or to the charged particle optical tube, wherein:
the diaphragm is positioned on the upper surface side of the second enclosure; and
the internal pressure of the second enclosure is kept equal to or higher than that of the first enclosure.

15. The charged particle beam apparatus according to claim 14, wherein:
the second enclosure has a cuboid-like shape of which at least one side is kept open;
a cover part is provided to cover the open side; and
a stage having the detector is fixed to the cover part.

16. The charged particle beam apparatus according to claim 15, further comprising a gas inlet port through which the atmosphere at least in a space between the detector and the sample can be replaced with a gas other than air, wherein the gas inlet port is fixed to the cover part.

17. The charged particle beam apparatus according to claim 16, further comprising an opening located below the gas inlet port, the opening communicating the inside and the outside of the second space.

18. The charged particle beam apparatus according to claim 15, wherein:
a signal amplifier for amplifying a signal from the detector is installed inside the second enclosure; and
the cover part includes a signal transmission part that outputs the signal from the signal amplifier to the outside of the second enclosure.
